(19) United States
(12) Patent Application Publication
(10) Pub. No.: US 2009/0309484 A1
(43) Pub. Date: Dec. 17, 2009

(54) DIRECT BAND-GAP NANODIAMOND CRYSTALS AND ULTRAVIOLET OPTICAL DEVICES USING THE SAME

(75) Inventors: Takao Sasagawa, Tokyo (JP); Zhi-Xun Shen, Stanford, CA (US)

Correspondence Address: LOWE HAUPTMAN HAM & BERNER, LLP, 1700 DIAGONAL ROAD, SUITE 300, ALEXANDRIA, VA, 22314, US

(73) Assignees: TOKYO INSTITUTE OF TECHNOLOGY, Tokyo (JP); THE BOARD OF TRUSTEES OF THE LELAND STANFORD JUNIOR UNIVERSITY, Palo Alto, CA (US)

(21) Appl. No.: 12/139,339

(22) Filed: Jun. 13, 2008

(51) Int. Cl. H01J 1/63; H01L 33/00

(52) U.S. Cl. 313/503; 257/77; 257/E33.013

(57) ABSTRACT

Novel direct band gap crystalline nanodiamonds and light emitting devices utilizing the direct band gap crystalline nanodiamonds are disclosed. With providing the detailed information on the electronic states and the electron band structure of several crystalline nanodiamonds, preferred device structures including an electroluminescence-based solid-state light source and a cathode-luminescence-based micro light source are shown. These devices emit light in the region of ultraviolet wavelength, which can be designed from 180 nm to 230 nm by a choice of nanodiamonds, with referring to the information provided in the present invention. The related applications of these UV light emitting devices include a light source for sterilization, a light source for decomposing harmful substances, a light source for spectroscopy, a light source for exciting a phosphor to emit a white light, a micro light source for micro optoelectronic devices, and a light source for writing a super high density recording media.

### BACKGROUND OF THE INVENTION

1. Field of the Invention

The present invention relates to direct band-gap nanodiamond crystals and optical devices in the region of ultraviolet wavelength by using the direct band-gap nanodiamond crystals. Light emitting devices with a tunable wavelength ranging from 180 nm to 230 nm, together with their applications, are also disclosed.

2. Description of the Related Art

Diamond is deemed to be the excellent material for the next generation of electronics. Pure diamond is a wide band gap material, showing exceptional physical properties such as extreme hardness, high reflective index, high melting point, and extremely high thermal conductivity. With carrier-doping, diamond becomes a semiconductor having high mobility of carriers (especially, of holes).

There have been a lot of studies on optical devices using diamond. One of the major reasons is the band gap value of diamond. The color or wavelength of light emitted from the semiconductor materials is determined by the band gap value between the conduction band and the valence band. For example, a blue light emitting diode (LED) with high brightness is made of gallium nitride (GaN) having a direct band-gap of about 3.4 eV. Diamond, on the other hand, has an indirect band gap of 5.5 eV, which corresponds to the wavelength of about 230 nm in the deep ultraviolet (UV) region.

Known light sources in the UV region (wavelength less than 400 nm) include a mercury lump, a heavy hydrogen lump, an excimer laser, a secondary higher harmonic wave emitting laser, and a synchrotron orbital radiation equipment. However, they have several drawbacks such as a large scale, a high cost, and a short lifetime, which impede them to be widely used. To overcome these problems, it has long been envisaged to realize solid-state optical devices in the UV light region. The benefit of solid-state devices (compact, inexpensive, long lifetime, etc) should expand the applications of UV optical devices. These applications include a light source for sterilization, a light source for decomposing harmful substances, a light source for spectroscopy, a light source for exciting a phosphor (e.g., used for a fluorescent lump without mercury), and a light source for writing a super high density recording media. Therefore, vigorous efforts have been made to develop such UV optical devices using diamond.

However, diamond has an intrinsic obstacle for the use of optical devices: it is an “indirect” band gap that diamond has. The characteristics and performances of optical devices depend on the electron band structure of the materials. For light emitting devices, materials having a direct band gap structure, in which the minimum of the conduction band and the maximum of the valence band are located at the same wave vector or momentum, are suitable because of their higher light emitting efficiencies. In contrast, indirect band gap materials suffer from poor light emitting efficiency, because recombination of an electron and a hole to emit light does not occur without gain and loss of a momentum.

Functionality of the diamond devices could be attained through nanotechnological approaches derived from nanodiamonds (alternatively, called as diamondoids, diamond molecules, or diamond nano-clusters). One of the prior art nanodiamond technologies by Yang et al. in Science 316, 1460 (2007) utilizes negative electron affinity of diamond molecules, realizing monochromatic electron emission. Other prior art by Dahl et al. in WO 2004/054047, the disclosure of which is incorporated therewith by reference, discloses optical uses of diamondoid-containing materials. According to this prior art, electron donating and withdrawing heteroatoms may be inserted into the diamond lattice without destroying the superior properties of diamond, thereby creating an N-type and P-type semiconducting diamonds. However, in this prior art, the fact that the band structure transforms from the “indirect” gap in bulk diamond to a “direct” gap in crystalline nanodiamonds, as revealed in the present invention, is completely overlooked, and therefore none of the advantages come from the direct band gap in crystalline nanodiamonds was utilized in their applications. Furthermore, owing to the lack of the detailed information on electronic structures in crystalline nanodiamonds, such an additional functionality as tunability of the band gap (or the wavelength of light emission/absorption) in a wide range in the UV light region has not been developed.

### BRIEF SUMMARY OF THE INVENTION

The present invention focuses on the electronic states and the electronic structure of crystalline nanodiamonds, providing the evidence of their direct band gap structure, by the first principles calculations based on the density functional theory, and provides direct band-gap nanodiamond crystals, which are novel.

The present invention also provides accurate evaluation of the band gap values with respect to the size of the nanodiamonds, which allows us to design any realistic optical devices using the crystalline nanodiamonds. As a result of quantum effects of the nanometer-size diamond, tunability of the wavelength of the light emission and absorption ranging from 180 nm to 230 nm is attained as an additional functionality of the nanodiamond-based UV optical devices.

The present invention further provides an UV light emitting device with a high efficiency, using the crystalline nanodiamonds as a direct, wide band gap material. In addition to the well known LED structure having a P-N junction, a simpler structure widely used for organic electroluminescence (EL) devices, which consists of an optoelectronic active layer (a crystalline nanodiamond layer in the present invention) sandwiched by electrode layers, can be used because of the direct band gap structure of the crystalline nanodiamonds. As a benefit of using the crystalline nanodiamonds, together with the detailed information of their electronic structure provided in the present invention, the wavelength of the emitted light can be designed from 180 nm to 230 nm by a choice of the size of nanodiamonds. Furthermore, thank to the EL structure without a P-N junction, an alternating current (AC) power source can be used for the device operation, which leads to simpler and smaller devices with superior performance. One of the electrodes in the EL structure will be a transparent electrode; thereby a large-area flat-panel UV light source can be fabricated. They will be useful, for example, as a compact and economical UV sterilizer in medical, biological, and other wide fields.

The present invention further includes a white light emitting device, which utilizes fluorescence of a phosphor layer fabricated on top of the transparent electrode in the nanodiamond-based UV light emitting device as mentioned hereinabove. This optical device can be an alternative white light source, which outstrips a conventional fluorescent lump in that it does not use mercury and it can be fabricated in a large-area flat-panel shape.

The present invention still further includes a micro UV light source (for micro optoelectronic devices and/or MEMS devices) comprising a crystalline nanodiamond with a direct band gap, which is used as a cathode-luminescent material. The micro UV beam emitting device is configured such that cathode luminescence is induced in a crystalline nanodiamond by the electron beam from an electron gun. The size of the light source can be reduced as small as the electron beam.

Other and further features, advantages, and benefits of the UV light emitting devices of the present invention will become apparent from the following detailed description thereof given by way of non-limiting example with reference to the attached drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A illustrates structures of diamond (a) and the smallest possible hydrogen-terminated nanodiamond C₁₀H₁₆ (b). Black lines indicate the conventional unit cell of diamond, in which the smallest possible diamond cage is highlighted.

FIGS. 1B and 1C illustrate crystal structures of the smallest nanodiamond C₁₀H₁₆. FIG. 1B shows only the diamond cages, while FIG. 1C shows a space-fill modeling.

FIG. 2 shows the lowest unoccupied molecular orbital (LUMO) for the smallest nanodiamond (C₁₀H₁₆) molecule (left (a)) and the wavefunctions of conduction band at the origin of the wave vector (k=0) for the crystalline nanodiamond C₁₀H₁₆ (right (b)).

FIGS. 3A and 3B show electronic structures of crystalline nanodiamond C₁₀H₁₆: the energy versus momentum relationship of electrons along the high symmetrical momentum points is shown in FIG. 3A, and the density of electronic states in FIG. 3B. Inset shows Brillouin zone for the tetragonal primitive cell with symmetry points labeled according to the standard notation.

FIGS. 4A to 4D show change in the electronic band structure with increasing the diamond cage. The energy dispersion relationship around the origin of the wave vector (the Γ point is k=0) for the crystalline adamantane (FIG. 4A), diamantane (FIG. 4B), triamantane (FIG. 4C), and bulk diamond (FIG. 4D).

FIG. 5 illustrates a UV light emitting device using a crystalline nanodiamond with a direct band gap according to the present invention.

FIG. 6 illustrates a nanodiamond-based optical device, configured as a white light emitting device, according to the present invention.

FIG. 7 illustrates a micro UV beam emitting device using a crystalline nanodiamond with a direct band gap according to the present invention.

### DETAILED DESCRIPTION OF THE INVENTION

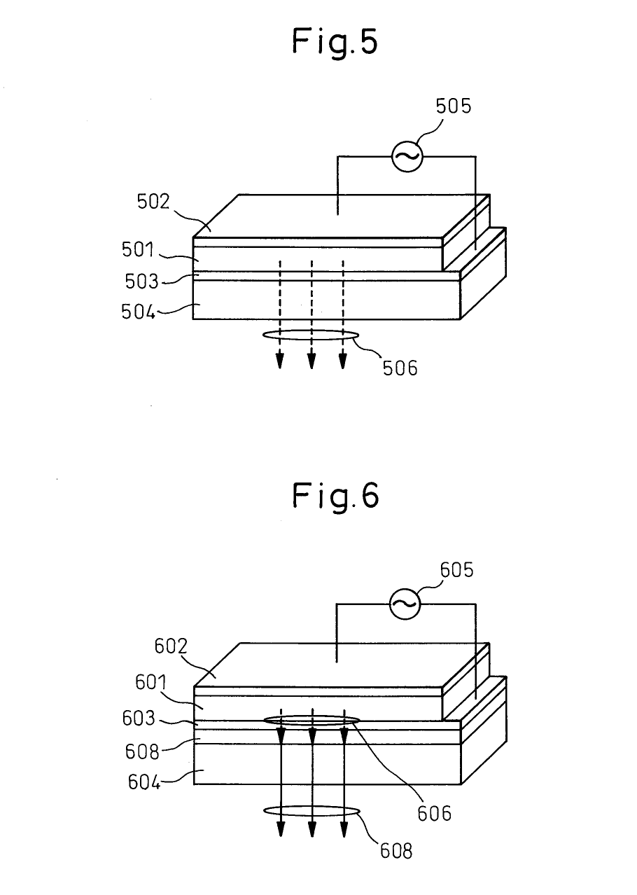

The present invention of direct band-gap nanodiamond crystals and nanodiamond-based ultraviolet light emitting devices will be described in more detail hereinafter with reference to the accompanying drawings, in particular to the examples of FIGS. 5-7, in which preferred embodiments of the invention are shown. This invention may, however, be embodied in different forms and should not be constructed as limited to only the embodiments set forth herein.

It is well known that, as similar to silicone (Si), diamond has an indirect band gap. This results from the fact that the valence band maximum (VBM) is located at the origin of the momentum (i.e. the wave vector k=0) whereas the conduction band minimum (CBM) is located at a finite wave vector. Because of this, recombination of an electron and a hole does not occur without gain and loss of a momentum, and therefore the efficiency of the electron-hole recombination and the accompanying light emission will be extremely low in light emitting devices using diamond. A straightforward way to overcome this problem is to transform the electron band structure of diamond into a direct band gap, in which the VBM and the CBM are located at the same wave vector.

As the first embodiment, the idea as to this transformation of the electronic structure of diamond into a direct band gap is disclosed hereinafter. The easiest approach to realize a direct band gap by making both the VBM and the CBM locate at the same momentum will be to shift only the CBM to the origin of the wave vector. In other word, a direct band gap structure of diamond is attained if the conduction band can be modified as an energy versus momentum relationship (or a band dispersion) with the parabolic dependence centered at k=0. Such a parabolic dispersion centered at k=0 can be found in alkaline metals, where the conduction electrons behave like nearly free electrons. By mimicking the situation in alkaline metals, we have successfully invented the way to realize a direct band gap structure of diamond.

The reason why the CBM is located at a finite wave vector is because the conduction electrons are rather localized around the carbon-carbon networks. The wave function of such electrons has a particular periodicity and thus a finite wave vector. Therefore, breaking the carbon-carbon network and delocalizing the conduction electrons will lead to what we are aiming at. This effect will show up particularly when the isolated diamond clusters are of the nanometer scale and arranged in a periodic structure like a crystal.

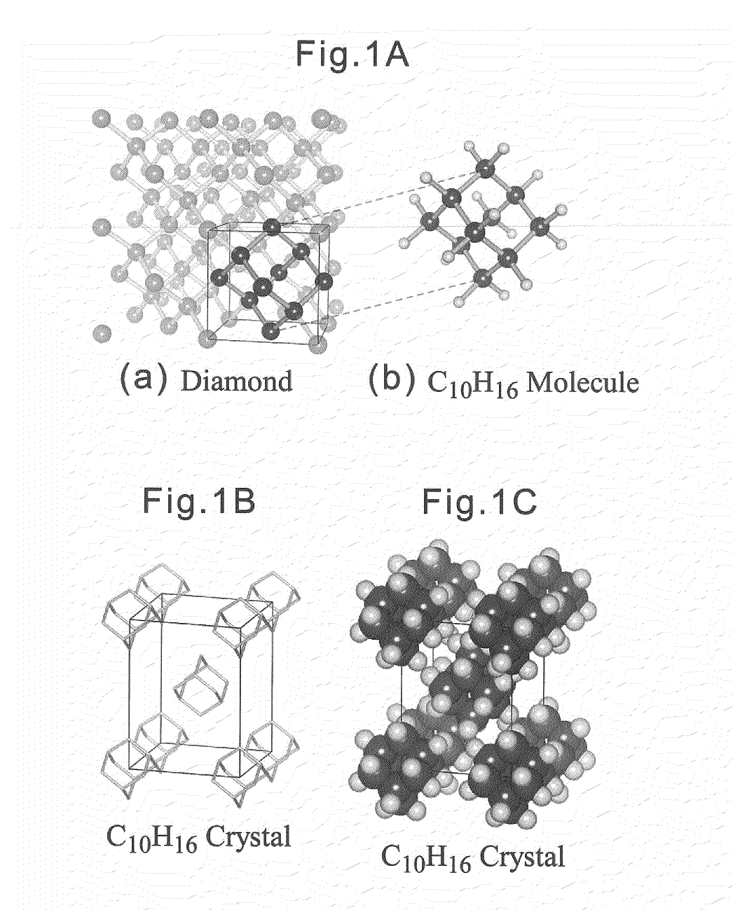

The crystal structure of diamond is two interpenetrating face-centered cubic (FCC) lattices; one shifts to (¼, ¼, ¼) with respect to the other, as shown in (a) of FIG. 1A. The ultimate form of nanodiamonds is a hydrocarbon molecule C₁₀H₁₄ (adamantane), which consists of a tetracyclic cage (the smallest possible diamond cage) of carbon atoms terminated by hydrogen atoms, as shown in (b) of FIG. 1A. With increasing the building blocks of this diamond fragment, an intriguing class of nano-material, known as diamondoids, is realized. In fact, purified higher diamondoids with up to 11 diamond cages are now available, thanks to the recent development of isolation techniques of them from crude oil as reported by Dahl et al. in Science 299, 96-99 (2003), of which disclosure is incorporated by reference.

In order to confirm the above mentioned our method of making a direct band gap structure of diamond, the electronic states and electron band structure of nanodiamonds in crystalline states was examined in detail by the first principles calculations in the framework of the density functional theory (DFT). DFT, developed by Hohenberg et al. and Kohn et al. (Phys. Rev. 136, B864-B871 (1964), and Phys Rev. 140, A1133-A1138 (1965)), is a quantum mechanical theory used in physics and chemistry to investigate the ground state of many-body systems, and is among the most popular and versatile methods available to investigate the electronic structure of solid-state materials.

First principles calculations based on DFT were performed within the generalized gradient approximation (GGA) as well as the local density approximation (LDA), using the pseudopotential plane-wave method with periodic boundary conditions. The Perdew-Burke-Ernzerhof and Teter-Pade parameterizations (Phys. Rev. Lett. 77, 3865-3868 (1996) and Phys. Rev. B 54, 1703-1710 (1996)) are used for the correlation and exchange potentials within GGA and LDA, respectively, and Troullier-Martins pseudopotentials, by Fuchs et al. (Comput. Phys. Commun. 119, 67 (1999)), are employed for the potentials of nuclei and core electrons. The plane-wave expansions of the electron density and potential with an energy cutoff of 100 Ry were used, which gave a total energy convergence better than a few meV per atom. The Brillouin zone was sampled with the Monkhorst-Pack scheme, as developed by Monkhorst et al., with the momentum grids finer than Δk=0.02 Å⁻¹. The smallest nanodiamond molecule, adamantane C₁₀H₁₄, crystallizes below T˜540 K. As reported by Nordman et al. in Acta Cryst. 18, 764-767 (1965), it has a tetragonal crystal structure (T<208 K) with the space group of P-42₁c (FIGS. 1C and 1D). The unit cell contains two C₁₀H₁₄ molecules. The lattice constants and the positions of atoms in the adamantane crystal were fully optimized theoretically in advance of the detailed examinations of electronic structures. Our calculated lattice constants of a=0.6533 nm and c=0.8823 nm are in excellent agreement with the experimental values of a=0.660 nm and c=0.881 nm. The average C—C bond length of 0.1542 nm in the crystalline adamantane is essentially the same with those in the isolated adamantane molecule and in the bulk diamond.

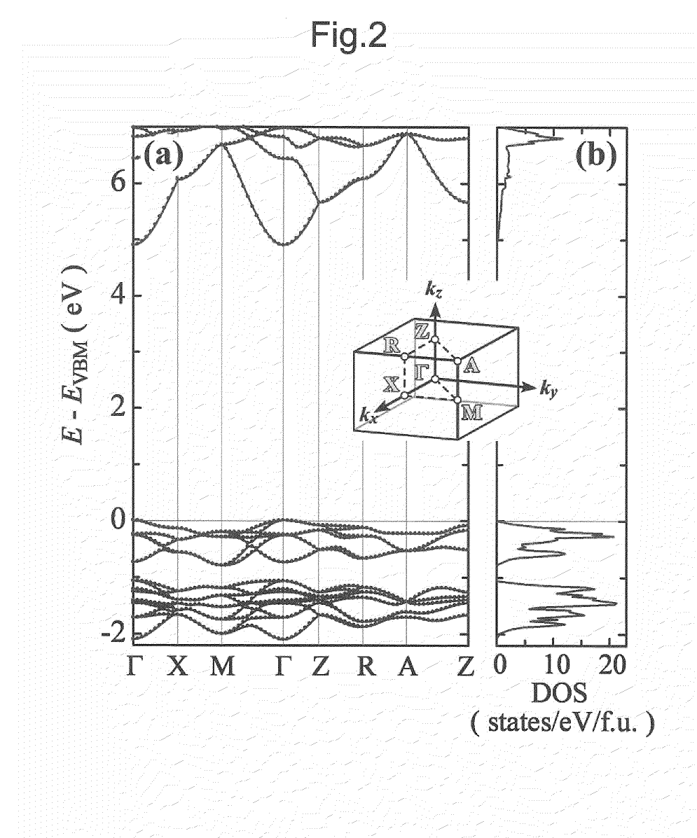

FIG. 2 illustrates the wavefunctions of the smallest nanodiamond, i.e. adamantane, from our results of calculations. FIG. 2(a) is the lowest unoccupied molecular orbital (LUMO) of the nanodiamond in an isolated state, demonstrating that the outer wavefunction of LUMO, which mainly comes from the hydrogen atoms surrounding the carbon diamond cage, is analogous to the s-orbital of electrons in that it is spherical without sign-change of the wavefunction along the circumference. Then, as shown in FIG. 2(b), the outer wavefunction of LUMO spreads over the space once the nanodiamonds turn into the crystalline state, indicating that the conduction electrons become delocalized. These results are exactly in accordance with our expectations.

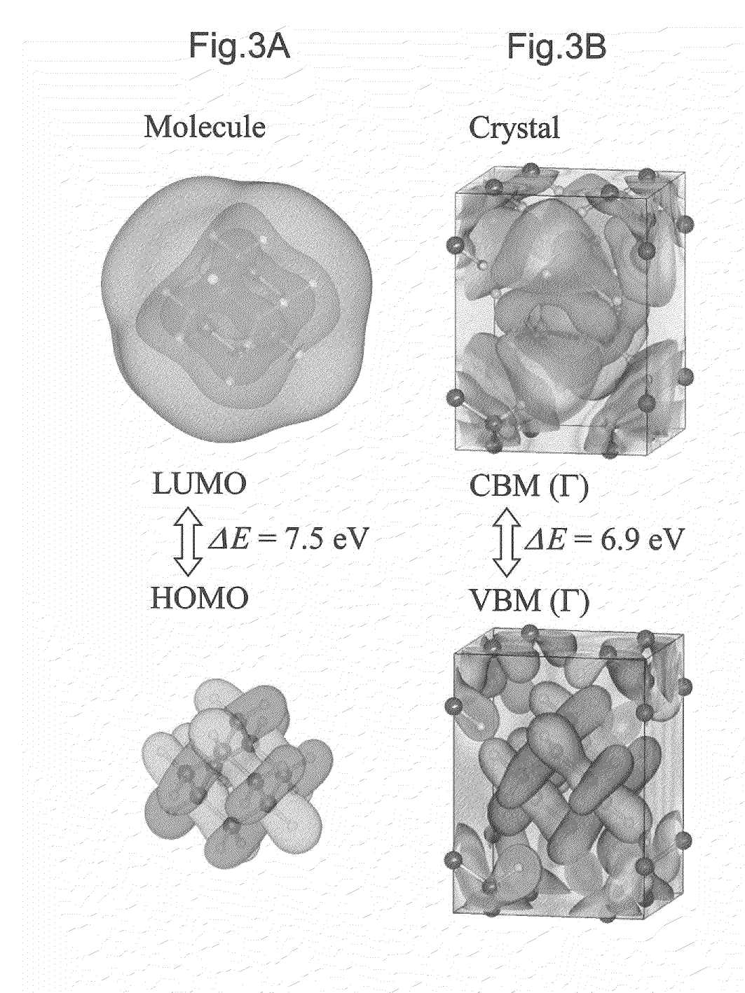

FIGS. 3A and 3B show the electronic band structure FIG. 3A and density of states FIG. 3B of crystalline adamantane. The GGA and LDA gave the almost identical band dispersions (i.e. the energy and momentum relationships of electrons in the crystal) and the electronic density of states, except for the excitation energy of electrons (energy gap) from the valence band to the conduction band. Before discussing the value of the energy gap quantitatively, we should point out here that the valence band maximum and the conduction band minimum in the crystalline adamantane take place at the same momentum, i.e. at the origin of the wave vector (here, the standard notation of Γ for k=0 is used), indicating it has a direct band gap. Obviously, this direct band gap structure results from the parabolic dispersion of the conduction band centered at k=0 (the Γ point).

It should be emphasized here again that whether the band gap is direct or indirect makes fundamental difference in the optoelectronic performance of semiconductors. The transition of electrons across the band gap in this energy range can accompany the absorption and emission of light, of which efficiency is far better in direct gap materials than that in the indirect ones. Since the bulk diamond has been studied as the candidate material for a light emitting device and a photon detector in the ultraviolet (UV) region, the present results should open a new frontier in this field of research.

In terms of the practical applications of the nanodiamonds into the optoelectronic devices, the accurate evaluation of the optical band gap values in the form of crystals is fundamentally important. Thus, the value of the energy gap is discussed in detail hereinafter. FIGS. 3A and 3B are the results from the GGA which gave the gap value E_{gap} of 4.8 eV, while the LDA (not shown here) resulted in E_{gap}=4.5 eV. It is well known (for example, refer to reports, Hybertsen et al., Phys. Rev. B 34, 5390 (1986) and Van Schilfgaarde et al., Phys. Rev. Lett. 96, 226402 (2006)) that, although the Kohn-Sham approach (i.e., the introduction of one electron energies) to DFT is powerful and successful, the band gaps of semiconductors and insulators are significantly underestimated in both the GGA and LDA cases. To overcome this problem, we have further employed self-energy corrections to the DFT Kohn-Sham eigenvalues by applying the GW approximation (G and W stand for the Green's function and the screened coulomb interaction, respectively), of which technique is described in a report by Hybertsen et al., Phys. Rev. 136, B864 (1964). As a reference calculation, the detailed electronic structures of the bulk diamond were evaluated with the same procedures and criteria. The indirect band gap value of E_{gap}=4.2 eV in the bulk diamond obtained from the GGA calculation was corrected to be 5.4 eV through the GW procedure, which should be compared with the experimental value of E_{gap}=5.5 eV found in textbooks (e.g. p 253 in “Electronic Structure and the Properties of Solid” by W. A. Harrison (Walter Ashley, 1930). Then, the crystalline adamantane was treated in the same way, and E_{gap}=6.9 eV was obtained as the final value of the direct band gap.

In the isolated nanodiamond, the level difference between the highest occupied molecular orbital (HOMO) and the lowest unoccupied molecular orbital (LUMO) corresponds to the energy gap, which is estimated to be E_{gap}=7.5 eV in our GGA+GW calculations. Upon reducing the size of the materials in the nanometer-scale, the quantum confinement of electrons in the systems should increase the energy gap. This is what we have observed in the isolated adamantane as the ˜2 eV increase of the energy gap from the bulk diamond. On the other hand, when the adamantane molecules are condensed into a crystal, molecular orbitals overlap each other to form electron bands, resulting in a decrease of the energy gap. Thus, the ˜0.6 eV reduction of the band gap from the isolated adamantane to the crystalline one is closely related to the formation of the electron band.

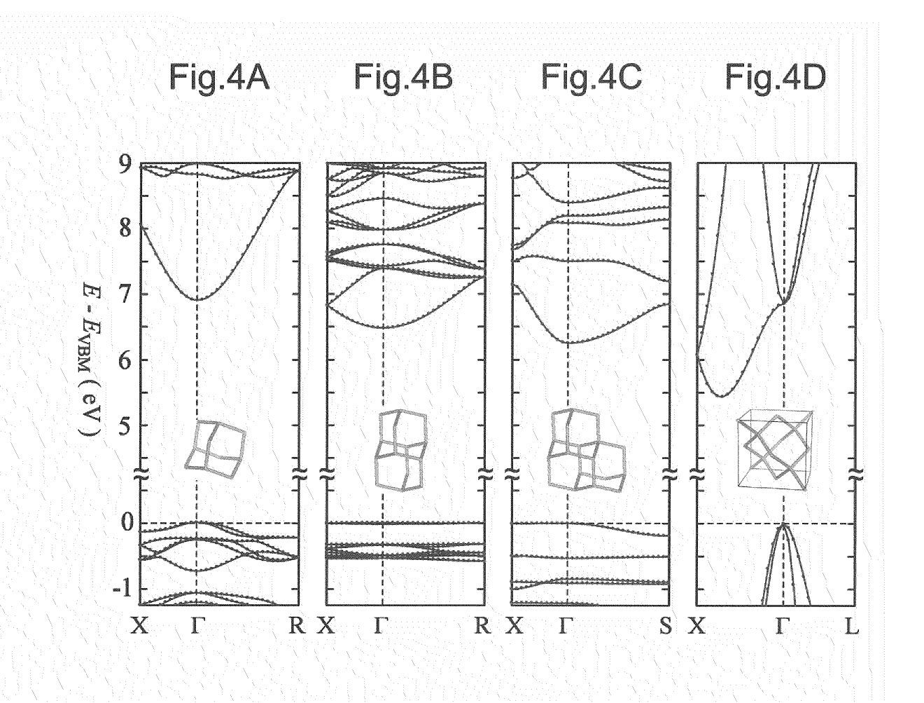

Accordingly, the band-gap values are determined by the balance between the quantum confinement and the band-formation of electrons in the solid state of nanodiamonds. This suggests that the band gap (and the corresponding wavelength of light emission and absorption) can be tuned by the choice of nanodiamonds. To quantify it, several larger nanodiamonds are further investigated in the same GGA+GW scheme. The second smallest nanodiamond is diamantane C₁₄H₂₀, which consists of 2 diamond cages and crystallizes in a cubic structure with the space group P3a as reported by Karle et al., J. Am. Chem. Soc. 87, 918 (1965). And then the next is triamantane C₁₈H₂₄ in an orthorhombic structure with space group Imm2 (the detailed crystallographic parameters were theoretically determined by us). FIGS. 4A to 4D summarize the electronic structures around the Γ (k=0) point in crystals of adamantane (FIG. 4A), diamantane (FIG. 4B), triamantane (FIG. 4C), and diamond (FIG. 4D). Irrespective of the different crystal structure and symmetry of nanodiamonds, the conduction band minima locate at the Γ (k=0) point in all the crystalline nanodiamonds [FIGS. 4A-4C], resulting in the direct band gap, which should be compared with the indirect band gap in bulk diamond due to the CBM in between the Γ and X (kₓ, k_{y}, k_{z}=2π/a, 0, 0) points [FIG. 4D]. It is also noticeable that, reflecting the degree of the quantum confinement in the isolated diamond molecules, the band gap value systematically decreases with increasing the number of the diamond cages. The corresponding wave length of light absorption and emission changes from ˜180 nm in adamantane to ˜200 nm in triamantane with increasing the size of nanodiamonds, and extrapolating to ˜230 nm in bulk diamond.

According to the afore-mentioned embodiments, highly efficient optical devices in the UV light region, of which wave length is tunable in the range from 180 nm to less than 230 nm, can be realized by using the crystalline nanodiamonds as a direct band gap material. The benefit of solid-state UV optical devices (compact, inexpensive, long lifetime, etc) will be enormous: for examples, a UV light emitting device can be used as a light source for sterilization, a light source for decomposing harmful substances, a light source for spectroscopy, a light source for exciting a phosphor (e.g., used for a fluorescent lump without mercury), a light source for writing a super high density recording media, and so forth.

A typical UV light emitting device using crystalline nanodiamonds is shown in FIG. 5. Because of the direct band gap structure of the crystalline nanodiamonds, as demonstrated hereinbefore in FIGS. 3A, 3B and 4A-4C, a simpler structure widely used for organic electroluminescence (EL) devices can be used, in addition to the well known LED (diode) structure having a P-N junction. It comprises a crystalline nanodiamond layer 501, which acts as an optoelectronic active layer, sandwiched by a metal electrode layer 502 and a transparent electrode layer 503. This layered structure is fabricated on a transparent substrate 504. Upon applying a voltage between the two electrodes 502-503 by a power supply 505, the UV light 506 comes out from 501 through 503 and 504.

Here, the wavelength of the emitted light 506 can be designed by a choice of the nanodiamond layer 501, as discussed hereinbefore by referring to FIG. 4A-4C. To be more specific, the emitted light is, for example, about 180 nm, 190 nm, and 200 nm, respectively, when the optoelectronic active layer is adamantane, diamantane, and triamantane. The nanodiamond layer 501 can be formed by evaporation, spin coating, etc. The transparent electrode layer 503 can be made of a known material, such as β-Ga₂O₃ and ultra-thin (˜2 nm) Au, which is electrically conductive and transparent to ultraviolet rays to be emitted by the device. The transparent substrate 504 can be made of a known material, such as Synthetic Silica Glass, LiF, MgF₂, and CaF₂, which is transparent to ultraviolet rays to be emitted by the emitting device.

In this configuration, in principle, it is easy to fabricate a large-area flat-panel-type light emitting device, and therefore, they will be useful, for example, as a compact and economical UV sterilizer used in medical, biological, and other wide fields.

Because it is the EL structure using the direct band gap material, an alternating current (AC) power source 505, in addition to a direct current (DC) power source, can be used for the device operation, and the alternating current (AC) power source leads to simpler and smaller devices with superior performance as compared to the diode structure with a P-N junction. The operation voltage should be higher than the band gap, and can be as high as a voltage to which the nanodiamond layer 501 can be durable, including AC 100V.

Needless to say, the present invention can be also applied to UV light emitting devices comprising a diode structure with a P-N junction, which has an advantage of a higher efficiency due to the direct band gap structure. The structure of a UV light emitting device can be the same as shown in FIG. 5, except that the crystalline nanodiamond layer 501 is replaced by P-type and N-type crystalline nanodiamond layers forming a P-N junction (not shown).

As a modification of the above-mentioned UV light emitting device, a white light source in a large-area flat-panel shape can be easily fabricated. FIG. 6 shows an example of such a white light emitting device. The device configuration from 601 to 605, as well as the emitted UV light 606, is exactly the same as 501-506 in the previous UV light emitting device in FIG. 5. The only difference is a phosphor layer 607 fabricated in between the transparent electrode 603 and the transparent substrate 604. When the device is operated by applying a voltage between the two electrodes 602-603, the UV light 606 emitted from the nanodiamond layer 601 stimulates the phosphor layer 607, leading to fluorescence of a white light 608 from 607. Here, the UV light 606 has a similar wave length produced by the discharged mercury gas in the conventional fluorescent lumps, thus any kind of phosphors already widely used in the fluorescent tube is available as the phosphor layer 607 in the present invention.

In addition to the several advantages as the solid-state light source (compact, inexpensive, long lifetime), this optical device is environmentally friendly in that it does not use mercury which is in general used in fluorescent lumps.

In accordance with the present invention, UV light receiving devices can be also manufactured by using direct band gap nanodiamond crystals of the present invention. Such UV light receiving devices can have similar structures as shown above for the UV light emitting devices, FIGS. 5 and 6, except that the light emitting layer of a direct band gap nanodiamond crystal acts as an UV light receiving layer instead of an UV light emitting layer and the electric power source is changed to an element which detects or utilizes a voltage generated by the UV light receiving device such as an UV sensor or detector.

One embodiment of the present invention further provides a micro UV light source used, for example, in micro optoelectronic devices and/or micro-electro-mechanical system (MEMS) devices, taking advantage of the cathode-luminescence of a nanodiamond with a direct band gap.

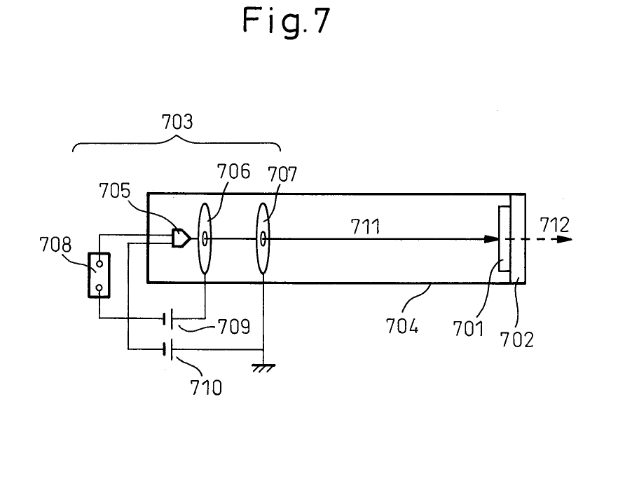

Referring to FIG. 7, a typical micro UV light source comprises a crystalline nanodiamond 701, which acts as a cathode luminescent material, on a transparent window 702, and an electron gun 703, which can be of any type (thermionic, field emission, etc.), in a vacuum container 704. As a typical example, 702 shown in FIG. 7 is a field emission electron gun, which consists of a cathode filament 705, an extracting electrode 706, an accelerating anode electrode 707, a flashing power supply 708, an extracting power supply 709, and an accelerating power supply 710. An electron beam 711 from the electron gun 703 travels in vacuum, and hits the crystalline nanodiamond 701 to emit micro UV light 712. The width of the electron beam 711 can be on the order of nanometers, so as to the induced micro UV beam 712. As discussed hereinbefore by referring to FIG. 4A-4C, the wavelength of the micro UV beam 712 is tunable by a choice of the nanodiamond 701 in such a way that about 180 nm with adamantane, about 190 nm with diamantane, and about 200 nm with triamantane.

The light emitting device of this type can be realized by utilizing a direct band gap material only, not by an indirect band gap material.

Various modifications of the exemplary embodiments of the invention disclosed hereinabove will be made by those skilled in the art. The invention is, therefore, to be construed as including all structure and methods that fall within the spirit and scope of the appended claims. All the disclosures in the references mentioned in this specification are incorporated herewith by reference thereto.

1. A direct band gap crystalline hydrogen-terminated nano-diamond.

2. An optoelectronic device comprising an optoelectronic active layer of a crystalline hydrogen-terminated nano-diamond having a direct band gap in a range of from more than 5.5 eV to 6.9 eV.

3. The optoelectronic device according to claim 2, wherein said crystalline hydrogen-terminated nano-diamond is an adamantane crystal having a tetragonal crystal structure of the space group of P-42₁c.

4. The optoelectronic device according to claim 2, wherein said crystalline hydrogen-terminated nano-diamond is a diamantane crystal having a cubic structure of the space group of P3a.

5. The optoelectronic device according to claim 2, wherein said crystalline hydrogen-terminated nano-diamond is a triamantane crystal having an orthorhombic crystal structure of the space group of Imm2.

6. The optoelectronic device according to claim 2, which is an UV light emitting device.

7. The optoelectronic device according to claim 2, which is an electroluminescent device.

8. The optoelectronic device according to claim 2, which is driven by an alternating (AC) current power source.

9. The optoelectronic device according to claim 2, wherein said direct band gap is tuned to a certain band gap in a range of from more than 5.5 eV to 6.9 eV.

10. The optoelectronic device according to claim 2, which is an UV light receiving device.

11. A light emitting device comprising a first electrode, a diamond layer on the first electrode, and a second electrode on the diamond layer, wherein said diamond layer is a crystalline hydrogen-terminated nano-diamond layer having a direct band gap in a range of from more than 5.5 eV to 6.9 eV and said second electrode has a main surface and transmits electromagnetic rays having a wavelength in a range of 180 nm to less than 230 nm, and wherein light is emitted outwardly from the main surface of said second electrode.

12. The light emitting device according to claim 11, wherein said diamond layer is an electroluminescent layer.

13. The light emitting device according to claim 11, wherein said light emitted has a wavelength in a range of from 180 nm to less than 230 nm.

14. The light emitting device according to claim 13, further comprising a phosphor layer on the side of said second electrode of said diamond layer, by which at least a portion of said light emitted from diamond layer and having a wavelength in a range of from 180 nm to less than 230 nm is absorbed by said phosphor layer and said phosphor layer then emits light having a wavelength different from the wavelength of said light emitted from diamond layer.

15. The light emitting device according to claim 11, which is one of the group consisting of a light source for sterilization, a light source for decomposing harmful substances, a light source for spectroscopy, a light source for exciting a phosphor and a light source for writing a super high density recording media.

16. An UV light micro beam emitting device comprising a vacuum chamber, an electron gun provided in said vacuum chamber for emitting an electron beam, a transparent window provided to said vacuum chamber, a cathode luminescent material provided between said electron gun and said transparent window for receiving an electron beam emitted from said electron gun to emit micro UV light beam which is emitted to outside said vacuum chamber through said transparent window.
